(19) United States
(12) Patent Application Publication
(10) Pub. No.: US 2022/0406641 A1
(43) Pub. Date: Dec. 22, 2022

(54) METHOD FOR MANUFACTURING SEMICONDUCTOR ELEMENT, AND SEMICONDUCTOR ELEMENT BODY

(71) Applicant: KYOCERA Corporation, Kyoto-shi, Kyoto (JP)

(72) Inventor: Keiichiro WATANABE, Kyoto-shi (JP)

(73) Assignee: KYOCERA Corporation, Kyoto-shi, Kyoto (JP)

(21) Appl. No.: 17/620,842

(22) PCT Filed: Jun. 25, 2020
(86) PCT No.: PCT/JP2020/025108

§ 371 Date: Dec. 20, 2021

(30) Foreign Application Priority Data
Jun. 28, 2019 (JP) 2019-121585

(51) Int. Cl. H01L 21/683; H01L 21/78

(52) U.S. Cl. CPC H01L 21/6836; H01L 21/78

(57) ABSTRACT

A method for manufacturing a semiconductor element according to the present disclosure includes an element layer forming step of forming a semiconductor element layer on a first surface of a ground substrate; a first supporting substrate preparing step of positioning a first supporting substrate that has a third surface and has a bonding material located on the third surface so that the third surface faces the first surface; a pressing step of causing the bonding material to enter a gap between the ground substrate and the semiconductor element layer; and a peeling step of peeling off the first supporting substrate, the bonding material, and the semiconductor element layer from the ground substrate.

### CROSS-REFERENCE TO RELATED APPLICATIONS

This application claims the priority of Japanese Patent Application No. 2019-121585, filed on Jun. 28, 2019, and the entire disclosure of the earlier application is incorporated herein by reference.

### TECHNICAL FIELD

The present disclosure relates to a method for manufacturing a semiconductor element, and a semiconductor element body.

### BACKGROUND ART

As a method for manufacturing a semiconductor element, a method for selectively growing a semiconductor element layer that can be singulated into a plurality of semiconductor elements on a ground substrate is known (see e.g., Patent Document 1). The grown semiconductor element layer is transferred to a supporting substrate, and after electrodes, conductor lines, and the like are formed, it is singulated into a plurality of semiconductor elements.

### CITATION LIST

### Patent Literature

Patent Document 1: JP 4638958 B

### SUMMARY

A method for manufacturing a semiconductor element according to the present disclosure includes an element layer forming step of forming, on a first surface of a ground substrate having the first surface, a semiconductor element layer having a second surface facing the first surface, and a connecting portion projecting out toward a side of the first surface on the second surface and connecting to the first surface; a step of disposing a reinforcement material that reinforces the semiconductor element layer around at least a part of the semiconductor element layer; and a peeling step of peeling off the reinforcement material and the semiconductor element layer.

A semiconductor element body of the present disclosure includes a supporting member having a main surface; a holding member located above the main surface; and a semiconductor element layer that is held on the main surface by way of the holding member, is extended in a first direction along the main surface, and has an opposing surface facing the main surface and a back surface on a side opposite to the opposing surface; where a projection extending in the first direction is located on one of the opposing surface and the back surface of the semiconductor element layer.

### BRIEF DESCRIPTION OF DRAWINGS

FIG. 1A is a view illustrating an element layer forming step of a first embodiment according to a method for manufacturing a semiconductor element according to the present disclosure, and is an end view taken along the cross-sectional line IA-IA in FIG. 1B.

FIG. 1B is a view illustrating the element layer forming step of the first embodiment, and is an end view taken along the cross-sectional line IB-IB in FIG. 1A.

FIG. 2A is a view illustrating a first supporting substrate preparing step of the first embodiment according to the method for manufacturing a semiconductor element according to the present disclosure, and is an end view taken along the cross-sectional line IIA-IIA in FIG. 2B.

FIG. 2B is a view illustrating the first supporting substrate preparing step of the first embodiment, and is an end view taken along the cross-sectional line IIB-IIB in FIG. 2A.

FIG. 3A is a view illustrating a pressing step of the first embodiment according to the method for manufacturing a semiconductor element according to the present disclosure, and is an end view taken along the cross-sectional line IIIA-IIIA in FIG. 3B.

FIG. 3B is a view illustrating the pressing step of the first embodiment, and is an end view taken along the cross-sectional line IIIB-IIIB in FIG. 3A.

FIG. 4A is a view illustrating a peeling step of the first embodiment according to the method for manufacturing a semiconductor element according to the present disclosure, and is an end view taken along the cross-sectional line IVA-IVA in FIG. 4B.

FIG. 4B is a view illustrating the peeling step of the first embodiment, and is an end view taken along the cross-sectional line IVB-IVB in FIG. 4A.

FIG. 5A is a view illustrating a second supporting substrate preparing step of the first embodiment according to the method for manufacturing a semiconductor element according to the present disclosure, and is an end view taken along the cross-sectional line VA-VA in FIG. 5B.

FIG. 5B is a view illustrating the second supporting substrate preparing step of the first embodiment, and is an end view taken along the cross-sectional line VB-VB in FIG. 5A.

FIG. 6A is a view illustrating a cleaving step of the first embodiment according to the method for manufacturing a semiconductor element according to the present disclosure, and is an end view taken along the cross-sectional line VIA-VIA in FIG. 6B.

FIG. 6B is a view illustrating the cleaving step of the first embodiment, and is an end view taken along the cross-sectional line VIB-VIB in FIG. 6A.

FIG. 7A is a view illustrating an exposure developing step of the first embodiment according to the method for manufacturing a semiconductor element according to the present disclosure, and is an end view taken along the cross-sectional line VIIA-VIIA in FIG. 7B.

FIG. 7B is a view illustrating the exposure developing step of the first embodiment, and is an end view taken along the cross-sectional line VIIB-VIIB in FIG. 7A.

FIG. 8A is a view illustrating a dividing step of the first embodiment according to the method for manufacturing a semiconductor element according to the present disclosure, and is an end view taken along the cross-sectional line VIIIA-VIIIA in FIG. 8B.

FIG. 8B is a view illustrating the dividing step of the first embodiment, and is an end view taken along the cross-sectional line VIIIB-VIIIB in FIG. 8A.

FIG. 9A is a view illustrating a protective film forming step of the first embodiment according to the method for manufacturing a semiconductor element according to the present disclosure, and is an end view taken along the cross-sectional line IXA-IXA in FIG. 9B.

FIG. 9B is a view illustrating the protective film forming step of the first embodiment, and is an end view taken along the cross-sectional line IXB-IXB in FIG. 9A.

FIG. 10A is a view illustrating a developing step of the first embodiment according to the method for manufacturing a semiconductor element according to the present disclosure, and is an end view taken along the cross-sectional line XA-XA in FIG. 10B.

FIG. 10B is a view illustrating the developing step of the first embodiment, and is an end view taken along the cross-sectional line XB-XB in FIG. 10A.

FIG. 11A is a view illustrating a peeling step of a second embodiment according to a method for manufacturing a semiconductor element according to the present disclosure, and is an end view taken along the cross-sectional line XIA-XIA in FIG. 11B.

FIG. 11B is a view illustrating the peeling step of the second embodiment, and is an end view taken along the cross-sectional line XIB-XIB in FIG. 11A.

FIG. 12A is a view illustrating an exposure developing step of the second embodiment according to the method for manufacturing a semiconductor element according to the present disclosure, and is an end view taken along the cross-sectional line XIIA-XIIA in FIG. 11B.

FIG. 12B is a view illustrating the exposure developing step of the second embodiment, and is an end view taken along the cross-sectional line XIIB-XIIB in FIG. 12A.

FIG. 13A is a view illustrating a second supporting substrate preparing step of the second embodiment according to the method for manufacturing a semiconductor element according to the present disclosure, and is an end view taken along the cross-sectional line XIIIA-XIIIA in FIG. 13B.

FIG. 13B is a view illustrating the second supporting substrate preparing step of the second embodiment, and is an end view taken along the cross-sectional line XIIIB-XIIIB in FIG. 13A.

FIG. 14A is a view illustrating a cleaving step of the second embodiment according to the method for manufacturing a semiconductor element according to the present disclosure, and is an end view taken along the cross-sectional line XIVA-XIVA in FIG. 14B.

FIG. 14B is a view illustrating the cleaving step of the second embodiment, and is an end view taken along the cross-sectional line XIVB-XIVB in FIG. 14A.

FIG. 15A is a view illustrating a supporting member attaching step of the second embodiment according to the method for manufacturing a semiconductor element according to the present disclosure, and is an end view taken along the cross-sectional line XVA-XVA in FIG. 15B.

FIG. 15B is a view illustrating the supporting member attaching step of the second embodiment, and is an end view taken along the cross-sectional line XVB-XVB in FIG. 15A.

FIG. 16A is a view illustrating a detachment step of the second embodiment according to the method for manufacturing a semiconductor element according to the present disclosure, and is an end view taken along the cross-sectional line XVIA-XVIA in FIG. 16B.

FIG. 16B is a view illustrating the detachment step of the second embodiment, and is an end view taken along the cross-sectional line XVIB-XVIB in FIG. 16A.

FIG. 17A is a view illustrating an element layer forming step of a third embodiment according to a method for manufacturing a semiconductor element according to the present disclosure, and is an end view taken along the cross-sectional line XVIIA-XVIIA in FIG. 17B.

FIG. 17B is a view illustrating the element layer forming step of the third embodiment, and is an end view taken along the cross-sectional line XVIIB-XVIIB in FIG. 17A.

FIG. 18A is a view illustrating a resist layer forming step of the third embodiment according to the method for manufacturing a semiconductor element according to the present disclosure, and is an end view taken along the cross-sectional line XVIIIA-XVIIIA in FIG. 18B.

FIG. 18B is a view illustrating the resist layer forming step of the third embodiment, and is an end view taken along the cross-sectional line XVIIIB-XVIIIB in FIG. 18A.

FIG. 19A is a view illustrating a resist portion forming step of the third embodiment according to the method for manufacturing a semiconductor element according to the present disclosure, and is an end view taken along the cross-sectional line XIXA-XIXA in FIG. 19B.

FIG. 19B is a view illustrating the resist portion forming step of the third embodiment, and is an end view taken along the cross-sectional line XIXB-XIXB in FIG. 19A.

FIG. 20A is a view illustrating a peeling step of the third embodiment according to the method for manufacturing a semiconductor element according to the present disclosure, and is an end view taken along the cross-sectional line XXA-XXA in FIG. 20B.

FIG. 20B is a view illustrating the peeling step of the third embodiment, and is an end view taken along the cross-sectional line XXB-XXB in FIG. 20A.

FIG. 21A is a view illustrating a supporting substrate preparing step of the third embodiment according to the method for manufacturing a semiconductor element according to the present disclosure, and is an end view taken along the cross-sectional line XXIA-XXIA in FIG. 21B.

FIG. 21B is a view illustrating the supporting substrate preparing step of the third embodiment, and is an end view taken along the cross-sectional line XXIB-XXIB in FIG. 21A.

FIG. 22A is a view illustrating a cleaving step of the third embodiment according to the method for manufacturing a semiconductor element according to the present disclosure, and is an end view taken along the cross-sectional line XXIIA-XXIIA in FIG. 22B.

FIG. 22B is a view illustrating the cleaving step of the third embodiment, and is an end view taken along the cross-sectional line XXIIB-XXIIB in FIG. 22A.

FIG. 23A is a perspective view illustrating one example of an embodiment of a semiconductor element body of the present disclosure.

FIG. 23B is a perspective view illustrating another example of the embodiment of the semiconductor element body of the present disclosure.

### DESCRIPTION OF EMBODIMENTS

Next, a method for manufacturing a semiconductor element of the present disclosure will be described below.

The method for manufacturing a semiconductor element of the present disclosure includes a semiconductor layer forming step, a step of disposing a reinforcement material, and a peeling step. The semiconductor layer forming step is a step of forming, on a first surface of a ground substrate having the first surface, a semiconductor element layer having a second surface facing the first surface and a connecting portion projecting out from the second surface toward a side of the first surface and connecting to the first surface. The step of disposing the reinforcement material is a step in which a reinforcement material for reinforcing the semiconductor element layer is disposed around at least a part of the semiconductor element layer. The peeling step is a step of peeling off the reinforcement material and the semiconductor element layer.

In the related art, when a semiconductor element layer grown on the ground substrate is transferred onto a supporting substrate, the semiconductor element layer is adhered to the supporting substrate, and the supporting substrate and the semiconductor element layer are peeled off from the ground substrate by applying mechanical force to the ground substrate and the supporting substrate. However, during peeling, the pattern of the semiconductor element layer grown on the ground substrate may easily break, and handling properties and the like of the semiconductor element layer after transfer may degrade. Therefore, the known method for manufacturing a semiconductor element has room for improvement in the handling properties of the semiconductor layer after transfer, and the like.

In contrast, according to the method for manufacturing a semiconductor element of the present disclosure, the handling properties of the semiconductor element layer can be improved. Furthermore, according to the semiconductor element body of the present disclosure, a semiconductor element body with improved handling properties can be provided.

Hereinafter, the method for manufacturing a semiconductor element of the present disclosure will be described in detail with reference to the drawings for each embodiment. The drawings are schematic and, for ease of explanation, are drawn with the dimensional ratios of the components emphasized. In addition, each of the drawings is given an orthogonal coordinate system XYZ for the sake of convenience of explanation.

### Method for Manufacturing Semiconductor Element

### First Embodiment

A first embodiment according to the method for manufacturing a semiconductor element according to the present disclosure includes an element layer forming step, and, as a step of disposing a reinforcement material, a first supporting substrate preparing step, a pressing step, and a peeling step.

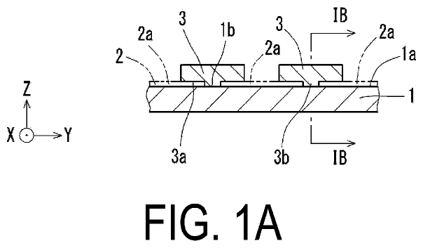

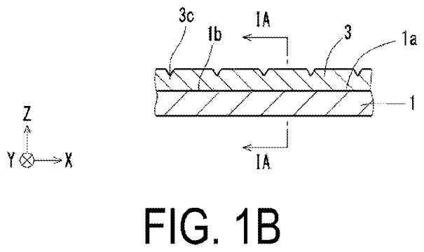

Each of the steps described above will be described primarily with reference to FIGS. 1A, 1B, 2A, 2B, 3A, 3B, 4A, and 4B.

In the element layer forming step, first, a ground substrate 1 for growing a semiconductor element layer 3 to become a plurality of semiconductor elements is prepared. One main surface (hereinafter also referred to as a first surface) 1a of the ground substrate 1 is a starting point for the growth of the semiconductor element layer. As the ground substrate 1, a GaN (gallium nitride) substrate cut out from a GaN single-crystal ingot so that the first surface 1a is in a predetermined plane direction is used. The ground substrate 1 may be an n-type substrate or a p-type substrate in which the nitride semiconductor is doped with impurities. Here, the “nitride semiconductor” is constituted by, for example, AlₓGa_{y}In_{z}N (0≤x≤1; 0 ≤y≤1;0≤z≤1; x+y+z=1). Furthermore, the ground substrate 1 may be, for example, a GaN template substrate in which a GaN layer is formed on a front surface of a silicon substrate, sapphire substrate, SiC substrate, or the like.

Next, a pattern of a mask 2 is formed so as to expose a part of the ground substrate 1 on the first surface 1a of the ground substrate 1. The pattern of the mask 2 defines a growth region of the semiconductor element layer 3, and is formed on the first surface 1in a predetermined pattern. In the present embodiment, the mask 2 has a stripe shape formed from a plurality of band-like portions 2a extending in a first direction (X direction) along the first surface 1a. A region (hereinafter, also referred to as “growth region”) 1b of the first surface 1a where the ground substrate 1 is exposed from the adjacent band-like portions 2a becomes the starting point for the growth of the semiconductor element layer 3. When viewed in plan along the Z direction of each of the band-like portions 2a, the width in the second direction (Y direction) intersecting the first direction (e.g., perpendicular) and parallel to the first surface 1a is, for example, 150 to 200 μm. The width of each growth region 1b in the second direction is, for example, 2 to 20 μm.

In the present embodiment, for example, a material containing silicon oxide such as SiO₂ is used as the mask material constituting the mask 2. The mask material merely needs to be a material in which the semiconductor element layer 3 does not grow by vapor-phase growth with the front surface of the mask 2 as the starting point. The mask material may be, for example, an oxide such as zirconium oxide (ZrOₓ), titanium oxide (TiOₓ), aluminum oxide (AlOₓ), or the like. The mask material may be a transition metal such as chromium (Cr), tungsten (W), molybdenum (Mo), tantalum (Ta), or niobium (Nb).

The mask 2 can be formed as follows. When the mask material is SiO₂, first, the SiO₂ layer is stacked to a thickness of approximately 100 to 500 nm by using a plasma chemical vapor deposition (PCVD) method or the like on the first surface 1a of the ground substrate 1. Thereafter, the mask 2 having a predetermined pattern can be formed by removing the unnecessary portion of the SiO₂ layer using a photolithography method and etching. As the etching, for example, wet etching using buffered hydrogen fluoride (BHF), which is a mixed aqueous solution of hydrofluoric acid and ammonium hydrogen fluoride, can be used. As a method for stacking the mask material, a method suitable for the mask material, such as vapor deposition, sputtering, or coating and curing can be appropriately used.

After the mask 2 is formed, the semiconductor element layer 3 is vapor-phase grown (epitaxial growth) from the growth region lb. The semiconductor element layer 3 is a nitride semiconductor layer in the present embodiment. As a method for growing the nitride semiconductor layer, a vapor-phase growth method such as a hydride vapor phase epitaxy (HVPE) method using a chloride of a group 13 element (group III) as a raw material, a metal organic chemical vapor deposition (MOCVD) method using an organic compound of a group 13 element as a raw material, or a molecular beam epitaxy (MBE) method can be used.

For example, when a GaN layer, which is a nitride semiconductor layer, is grown using the MOCVD method, first, the ground substrate 1 on which the mask 2 is formed is inserted into the reaction chamber of the epitaxial device. Then, the ground substrate 1 is heated to a predetermined temperature while hydrogen gas, nitrogen gas, or a mixed gas of hydrogen and nitrogen, and a gas such as ammonia containing a group 15 element (group V) are supplied into the reaction chamber. After the temperature of the ground substrate 1 becomes stable, a semiconductor crystal is grown from the growth region 1b of the ground substrate 1 by supplying an organic compound of a group 13 element such as trimethylgallium, in addition to hydrogen gas, nitrogen gas, or a mixed gas of hydrogen and nitrogen, as well as gas containing a group 15 element.

When growing a GaN layer, a GaN layer of a desired conductivity type can be grown by supplying a raw material gas containing an n-type impurity such as Si or a p-type impurity such as Mg into the reaction chamber. Thus, the semiconductor element layer 3 can be a multi-layer film that functions as a semiconductor laser (laser diode; LD) or a light emitting diode (LED).

The semiconductor element layer 3 is selectively grown in the growth region lb, and then laterally grown on the mask 2. The lateral growth of the semiconductor element layer 3 is stopped before portions of the semiconductor element layer 3 grown from the adjacent growth regions 1b come into contact. As a result, the portions of the semiconductor element layer 3 grown from the adjacent growth regions 1b come into contact with each other, and crystal defects such as cracks or threading dislocations can be prevented from occurring in the semiconductor element layer 3.

In the element layer forming step, after the semiconductor element layer 3 is grown, a plurality of frangible portions 3c are formed in the semiconductor element layer 3. The frangible portions 3c are the starting points of cleavage when cleaving the semiconductor element layer 3. Forming the frangible portions 3c facilitates the cleaving of the semiconductor element layer 3 in a subsequent cleaving step. The plurality of frangible portions 3c may be formed at predetermined intervals along the first direction. The interval between adjacent frangible portions 3c may be substantially the same as the dimension in the first direction of the semiconductor element to be manufactured. In the present embodiment, for example, as illustrated in FIG.1B, the plurality of frangible portions 3c located at a plurality of locations in the first direction (X direction) are thinned portions in which a recessed portion such as a notch is formed. The frangible portions 3c can be formed using, for example, wet etching using an anisotropic etchant, machining using a mechanical tool, or laser processing. Alternatively, the semiconductor element layer 3 including the frangible portions 3c can be grown by adjusting the growth conditions of the semiconductor element layer 3.

After forming the frangible portions 3c in the semiconductor element layer 3, the mask 2 is removed using an etchant that substantially does not affect the semiconductor element layer 3. When the mask 2 is constituted by SiO₂, HF(hydrofluoric acid)-based wet etching is performed. The etching removes the mask 2 to obtain a semiconductor element layer 3 that extends in a first direction (X direction), for example, as illustrated in FIGS. 1A and 1B. The semiconductor element layer 3 includes a second surface 3a facing the first surface 1a of the ground substrate 1 and a connecting portion 3b projecting out from the second surface 3a toward the side of the first surface 1a and connecting to the first surface 1a. The connecting portion 3b extends in the first direction along the first surface 1a of the ground substrate 1, and is located on a part of the second surface 3a in the second direction. As illustrated in FIG. 1A, for example, the semiconductor element layer 3 is substantially T-shaped when viewed in a cross section perpendicular to the first direction. This shape facilitates peeling of the semiconductor element layer 3 from the ground substrate 1 in the subsequent peeling step. The connecting portion 3b may be located at a center portion of the second surface 3a in the second direction.

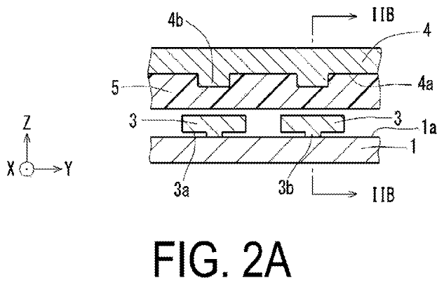

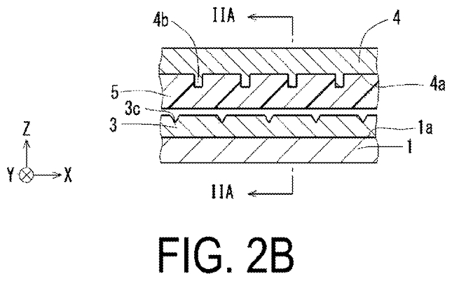

In the first supporting substrate preparing step, first, a first supporting substrate 4 having a third surface 4a is prepared. Next, as illustrated in FIGS. 2A and 2B, for example, the first supporting substrate 4 is positioned so that the third surface 4a faces the first surface 1a of the ground substrate 1. As the first supporting substrate 4, for example, a SiO₂ substrate, an indium tin oxide (ITO) substrate, a Si substrate, or the like can be used. A plastic bonding material 5 is applied to the third surface 4a. In the present embodiment, a thermoplastic bonding material is used as the bonding material 5. In addition to thermoplastic properties, the bonding material 5 has light curing properties or light softening properties. As the bonding material 5, for example, a resist material for nanoimprint such as an alicyclic epoxy resin-based material can be used.

A plurality of first protruding portions 4b are located on the third surface 4a of the first supporting substrate 4. The third surface 4a on which the plurality of first protruding portions 4b are located can be formed by, for example, dry etching or wet etching. The plurality of first protruding portions 4b are covered by the bonding material 5. The plurality of first protruding portions 4b are located at predetermined intervals along a linear direction parallel to the third surface 4a (X direction illustrated in FIGS. 2A and 2B). The interval between adjacent first protruding portions 4b may be substantially the same as the interval between adjacent frangible portions 3c in the first direction, that is, the dimension in the first direction of the semiconductor element to manufacture. As a result, the mounting precision of the semiconductor element can be improved and misalignment can be reduced.

In the first supporting substrate preparing step, as illustrated in FIGS. 2A and 2B, for example, the first supporting substrate 4 may be positioned so that the plurality of first protruding portions 4b and the plurality of frangible portions 3c are alternately adjacent to each other in plan view. This facilitates the cleaving of the semiconductor element layer 3 in the subsequent cleaving step. Thus, as illustrated in FIG. 2B, for example, the first supporting substrate 4 may be positioned so that, in the first direction, each first protruding portion 4b is located between, and particularly midway between, two frangible portions 3c adjacent to the first protruding portion 4b. In addition, as illustrated in FIG. 2A, for example, the first supporting substrate 4 may be positioned so that the plurality of first protruding portions 4b are located at the center portion of the semiconductor element layer 3 in the second direction. At this time, a fluororesin molecular film having a thickness of approximately several nm may be formed on the first surface 1a to facilitate peeling in the subsequent peeling step.

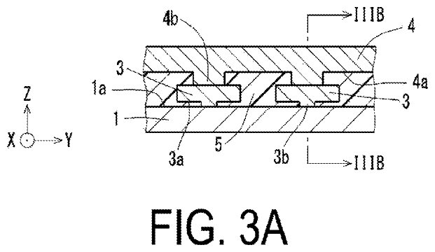

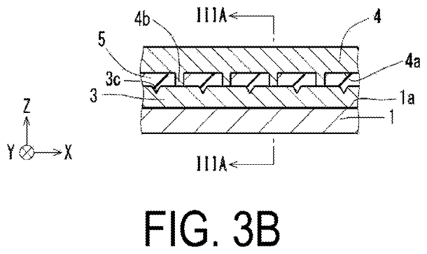

In the pressing step, the bonding material 5 is first softened. Next, the first supporting substrate 4 is pressed against the ground substrate 1, and as illustrated in FIGS. 3A and 3B, for example, the softened bonding material 5 is caused to enter the gap between the first surface 1a and the second surface 3a. If the bonding material 5 is thermoplastic, the bonding material 5 can be softened by heating. The pressing of the first supporting substrate 4 against the ground substrate 1 may be performed in a vacuum chamber having a predetermined degree of vacuum. As a result, the infiltration of the bonding material 5 into the gap between the first surface 1a and the second surface 3a is less likely to be inhibited by a gas such as air present in the gap.

In the pressing step, the first supporting substrate 4 may be relatively pressed against the ground substrate 1. In other words, the ground substrate 1 may be fixed and the first supporting substrate 4 may be pressed toward the ground substrate 1, or the first supporting substrate 4 may be fixed and the ground substrate 1 may be pressed toward the first supporting substrate 4. Alternatively, both the ground substrate 1 and the first supporting substrate 4 may be pressed so as to approach each other.

The pressing of the first supporting substrate 4 against the ground substrate 1 may be performed while exhausting a gas present in the gap between the first surface 1a and the second surface 3a to the outside. This exhaust can be performed, for example, by forming a plurality of through holes that pass through the ground substrate 1 from the first surface la to the other main surface 1c, and causing the gas to be suctioned from the other main surface 1c side through the plurality of through holes. The plurality of through holes may be formed so that, for example, the openings in the first surface 1a overlap with the semiconductor element layer 3 in a plan view and are located in a region different from the growth region 1b.

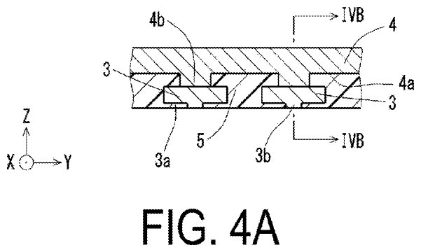

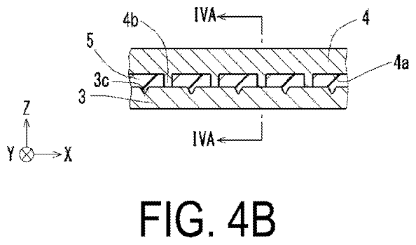

In the peeling step, the bonding material 5 is cooled and cured. Next, the first supporting substrate 4, the cured bonding material 5, and the semiconductor element layer 3 are peeled off from the ground substrate 1 by separating the first supporting substrate 4 and the ground substrate 1 relative to each other. In the method for manufacturing a semiconductor element according to the present embodiment, as illustrated in FIGS. 4A and 4B, for example, the semiconductor element layer 3 formed on the first surface 1a of the ground substrate 1 is peeled from the ground substrate 1 while being held by the cured bonding material 5. As a result, the bonding material 5 functions as a reinforcement material that reinforces the semiconductor element layer 3, and the pattern of the semiconductor element layer 3 grown on the ground substrate 1 can be made less likely to break when it is peeled off from the ground substrate 1, thereby improving the handling properties of the semiconductor element layer 3.

In the method for manufacturing a semiconductor element of the present embodiment, a second supporting substrate preparing step and a cleaving step may be performed after the peeling step.

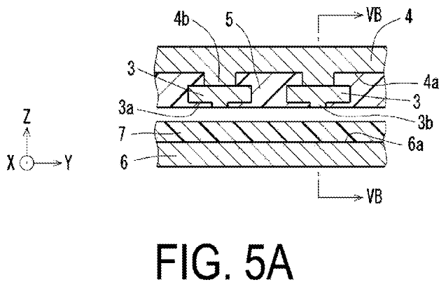

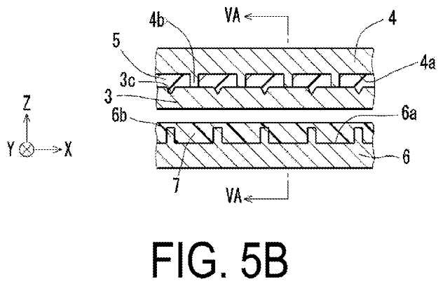

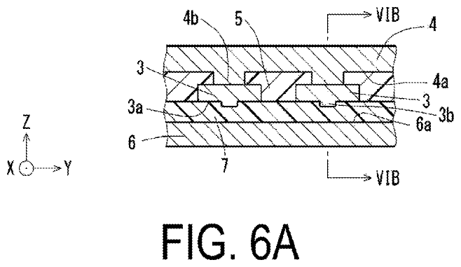

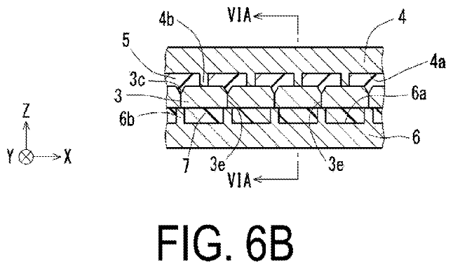

Each of the steps described above will be described primarily with reference to FIGS. 5A, 5B, 6A, and 6B.

In the second supporting substrate preparing step, first, a second supporting substrate 6 having a fourth surface 6a is prepared. As the second supporting substrate 6, for example, a SiO₂ substrate, an ITO substrate, a Si substrate, or the like can be used. A plurality of second protruding portions 6b are located on the fourth surface 6a of the second supporting substrate 6. The fourth surface 6a on which the plurality of second protruding portions 6b are located can be formed by dry etching or wet etching. The plurality of second protruding portions 6b may be located at predetermined intervals along a linear direction parallel to the fourth surface 6a (X direction illustrated in FIGS. 5A and 5B). The interval between adjacent second protruding portions 6b may be substantially the same as the interval between adjacent frangible portions 3c in the first direction, that is, the dimension in the first direction of the semiconductor element to be manufactured. Furthermore, a resist material 7 having light curing properties or light softening properties is applied to the fourth surface 6a. As the resist material 7, for example, a resist material for nanoimprint can be used.

Next, in the second supporting substrate preparing step, as illustrated in FIGS. 5A and 5B, for example, the second supporting substrate 6 is positioned so that the fourth surface 6a faces the third surface 4a of the first supporting substrate 4, and the plurality of second protruding portions 6b are alternately adjacent to the plurality of first protruding portions 4b in plan view. In the second supporting substrate preparing step, the second supporting substrate 6 may be positioned so that the plurality of second protruding portions 6b overlap corresponding ones of the plurality of frangible portions 3c in plan view.

In the cleaving step, the bonding material 5 is softened, and then the second supporting substrate 6 is pressed against the first supporting substrate 4. As a result, stress is generated in portions of the semiconductor element layer 3 against which the plurality of second protruding portions 6b respectively abut, and as illustrated in FIGS. 6A and 6B, for example, a plurality of cleaving surfaces 3e can be formed on the semiconductor element layer 3.

In the present embodiment, the second supporting substrate 6 is pressed against the first supporting substrate 4 after the bonding material 5 has been softened while being positioned so that the plurality of first protruding portions 4b and the plurality of second protruding portions 6b are alternately adjacent to each other in plan view. As a result, stress can be concentrated at the frangible portions 3c of the semiconductor element layer 3, thereby allowing for precise cleaving of the semiconductor element layer 3. In plan view, when the plurality of first protruding portions 4b and the plurality of frangible portions 3c are alternately adjacent to each other, and the plurality of second protruding portions 6b overlap corresponding ones of the plurality of frangible portions 3c, stress can be effectively concentrated at the frangible portions 3c, thereby allowing for precise cleaving of the semiconductor element layer 3. Furthermore, when a transparent substrate such as a SiO₂ substrate or an ITO substrate is used as the first supporting substrate 4 and the second supporting substrate 6, the positioning of the first supporting substrate 4 and the second supporting substrate 6 and the semiconductor element layer 3 can be performed using an optical method. This allows for more precise cleaving of the semiconductor element layer 3.

In the method for manufacturing a semiconductor element of the present embodiment, after the cleaving step, an exposure developing step, which is a removing step for removing a part of the bonding material 5, a dividing step, a protective film forming step, and a developing step may be performed.

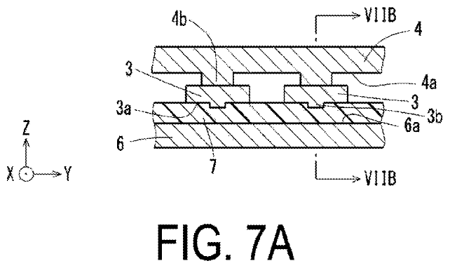

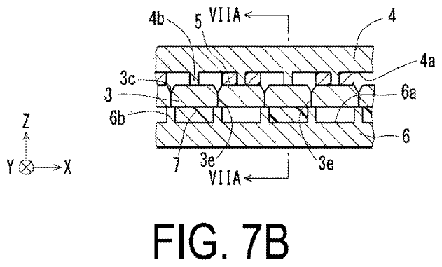

Each of the steps described above will be described primarily with reference to FIGS. 7A, 7B, 8A, 8B, 9A, 9B, 10A, and 10B.

In the exposure developing step, the bonding material 5 applied to the third surface 4a of the first supporting substrate 4 and the resist material 7 applied to the fourth surface 6a of the second supporting substrate 6 are selectively exposed, and the bonding material 5 and the resist material 7 are developed after exposure. As a result, as illustrated in FIGS. 7A and 7B, for example, the semiconductor element layer 3 is such that a semiconductor element precursor (hereinafter, also referred to as an element part) 31 held by the first supporting substrate 4, and the element part 31 held by the second supporting substrate are alternately adjacent to each other in the first direction.

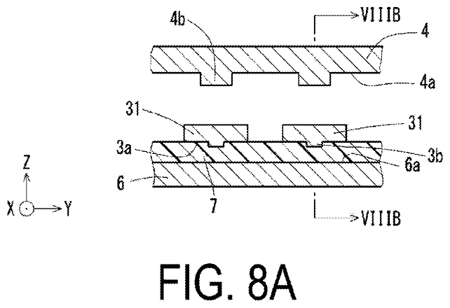

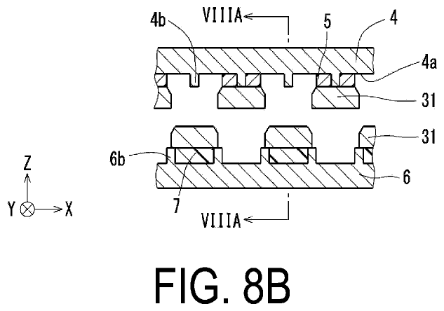

In the dividing step, the first supporting substrate 4 and the second supporting substrate 6 are relatively separated. Thus, as illustrated in FIGS. 8A and 8B, for example, a plurality of element parts 31 held by the first supporting substrate 4 or the second supporting substrate 6 are obtained.

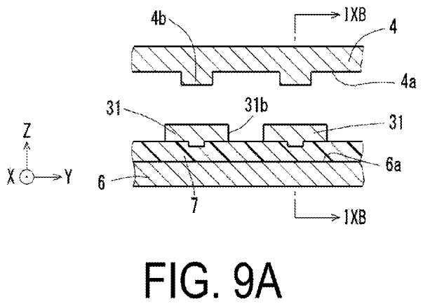

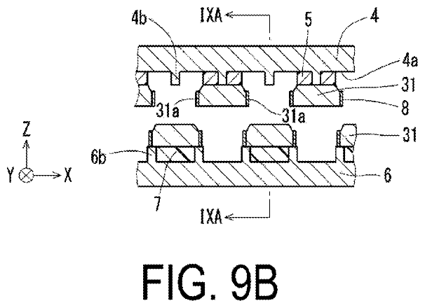

In the protective film forming step, as illustrated in FIGS. 9A and 9B, for example, a protective film 8 is formed on both end faces 31a in the first direction of each element part 31. As a material of the protective film 8, for example, Al₂O₃, SiO₂, Ta₂O₅, and the like may be used. For example, a vapor deposition method can be used as the method for forming the protective film 8. In the present embodiment, an oblique vapor deposition method is used to vapor deposit the protective film 8 on both end faces 31a. As a result, the protective film 8 can be formed collectively on the plurality of element parts 31 while the plurality of element parts 31 are being held by the first supporting substrate 4 or the second supporting substrate 6. Note that when performing the oblique vapor deposition, the protective film is not vapor deposited on the side surface 31b by covering the surface where the formation of the protective film 8 is not necessary, for example, the side surface 31b in the second direction of each element part 31 with a metal mask.

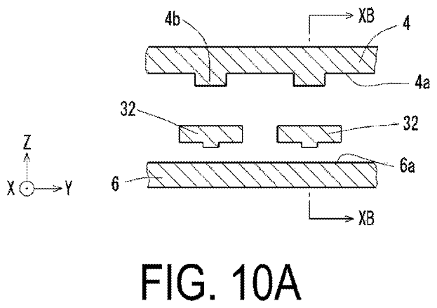

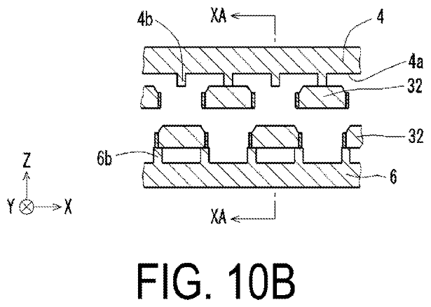

In the developing step, the bonding material 5, the resist material 7, and the metal mask used in the protective film forming step are removed by dry etching or wet etching. As a result, as illustrated in FIGS. 10A and 10B, for example, a plurality of semiconductor elements 32 held by the first supporting substrate 4 or the second supporting substrate 6 are obtained.

According to the method for manufacturing a semiconductor element of the present embodiment, when peeling off the semiconductor element layer 3 from the ground substrate 1, the pattern of the semiconductor element layer 3 grown on the ground substrate 1 can be made less likely to break, thereby improving the handling properties of the semiconductor element layer 3. This allows for precise cleaving of the semiconductor element layer 3.

### Second Embodiment

Next, a method for manufacturing a semiconductor element according to a second embodiment will be described. The method for manufacturing a semiconductor element according to the second embodiment includes an element layer forming step, a first supporting substrate preparing step, a pressing step, and a peeling step. In the method for manufacturing a semiconductor element according to the second embodiment, the exposure developing step, the second supporting substrate preparing step, and the cleaving step are performed after the peeling step. The element layer forming step, the first supporting substrate preparing step, the pressing step, and the peeling step of the method for manufacturing a semiconductor element according to the second embodiment are respectively the same as the element layer forming step, the first supporting substrate preparing step, the pressing step, and the peeling step of the method for manufacturing the semiconductor element according to the first embodiment. In the following, description of the element layer forming step, the first supporting substrate preparing step, and the pressing step of the method for manufacturing the semiconductor element according to the second embodiment will be omitted, and the steps after the peeling step will be described.

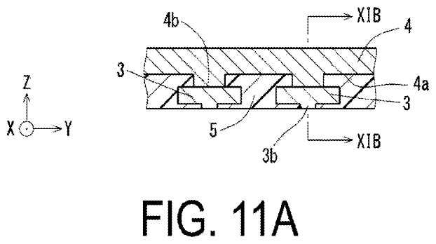

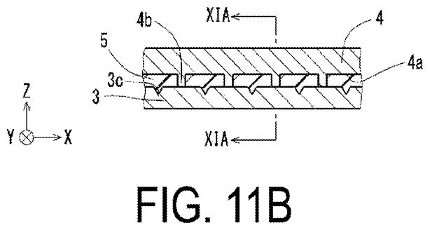

Each of the steps described above will be described primarily with reference to FIGS. 11A, 11B, 12A, 12B, 13A, 13B, 14A, and 14B.

In the peeling step, as illustrated in FIGS. 11A and 11B, for example, the semiconductor element layer 3 formed on the first surface 1a of the ground substrate 1 is peeled off from the ground substrate 1 while being held by the cured bonding material 5, similar to the peeling step of the first embodiment. As a result, the pattern of the semiconductor element layer 3 grown on the ground substrate 1 can be made less likely to break when it is peeled off from the ground substrate 1, thereby improving the handling properties of the semiconductor element layer 3.

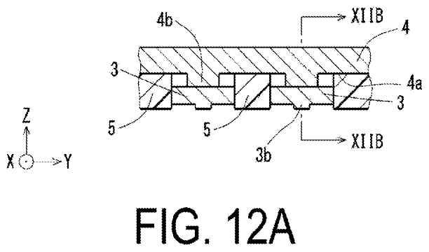

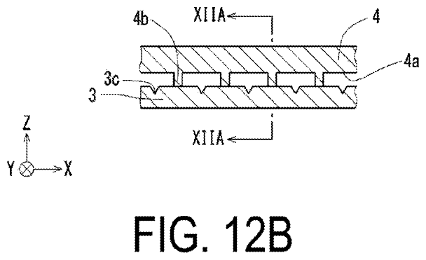

In the exposure developing step, only a portion of the cured bonding material 5 that completely overlaps the semiconductor element layer 3 in a plan view is removed as illustrated in FIGS. 12A and 12B, for example, using a photolithography method and dry etching or wet etching. As a result, the semiconductor element layer 3 can be held by the first supporting substrate 4 by way of the cured bonding material 5. The bonding material 5 is substantially not in contact with the second surface 3a of the semiconductor element layer 3 and the surface on the side opposite to the second surface 3a, but in contact with only both side surfaces in the second direction (Y direction) of the semiconductor element layer 3. For example, a Cr mask, a Ti mask, a W mask, or the like can be used as the photomask used in the photolithography method.

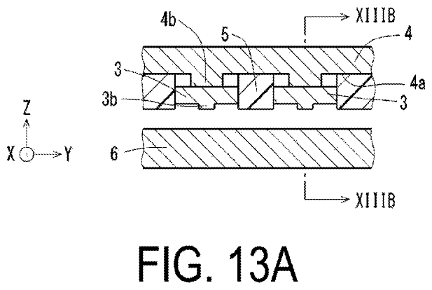

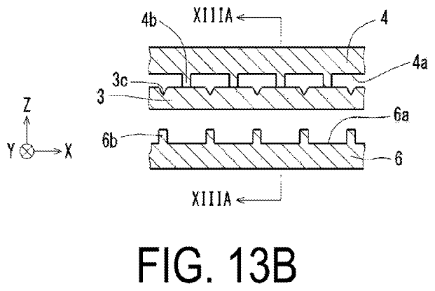

In the second supporting substrate preparing step, first, a second supporting substrate 6 having a fourth surface 6a is prepared. As the second supporting substrate 6, for example, a SiO₂ substrate, an ITO substrate, a Si substrate, or the like can be used. A plurality of second protruding portions 6b are located on the fourth surface 6a of the second supporting substrate 6. The fourth surface 6a on which the plurality of second protruding portions 6b are located can be formed by, for example, dry etching or wet etching. The plurality of second protruding portions 6b may be located at predetermined intervals in a linear direction parallel to the fourth surface 6a (X direction illustrated in FIGS. 13A and 13B). The interval between adjacent second protruding portions 6b may be substantially the same as the interval between adjacent frangible portions 3c in the first direction, that is, the dimension in the first direction of the semiconductor element to be manufactured.

Next, in the second supporting substrate preparing step, the second supporting substrate 6 is located such that the fourth surface 6a faces the third surface 4a of the first supporting substrate 4, and the plurality of second protruding portions 6b are alternately adjacent to the plurality of first protruding portions 4b in plan view, for example, as illustrated in FIG. 13B. In the second supporting substrate preparing step, the second supporting substrate 6 may be positioned so that the plurality of second protruding portions 6b overlap corresponding ones of the plurality of frangible portions 3c in plan view.

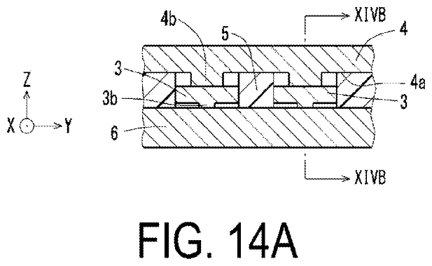

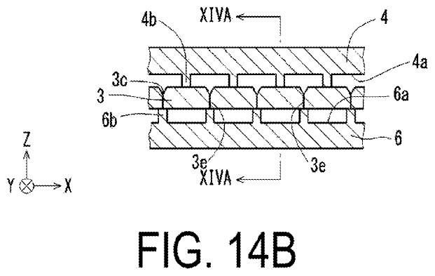

In the cleaving step, the second supporting substrate 6 is pressed against the first supporting substrate 4. As a result, stress is generated in portions of the semiconductor element layer 3 against which the plurality of second protruding portions 6b respectively abut, and a plurality of cleaving surfaces 3e are formed in the semiconductor element layer 3, for example, as illustrated in FIG. 14B. In the present embodiment, the second supporting substrate 6 is pressed against the first supporting substrate 4 in a state in which the bonding material 5 is not in contact with the third surface 3a of the semiconductor element layer 3 and the surface on the side opposite to third surface 3a, and the plurality of second protruding portions 6b are alternately adjacent to the plurality of first protruding portions 4b in plan view. This allows for precise cleaving of the semiconductor element layer 3 because stress can be concentrated at the frangible portions 3c. In plan view, when the plurality of first protruding portions 4b and the plurality of frangible portions 3c are alternately adjacent to each other, and the plurality of second protruding portions 6b overlap corresponding ones of the plurality of frangible portions 3c, stress can be effectively concentrated at the frangible portions 3c, thereby allowing for more precise cleaving of the semiconductor element layer 3. Furthermore, when a transparent substrate such as a SiO₂ substrate or an ITO substrate is used as the first supporting substrate 4 and the second supporting substrate 6, the positioning of the first supporting substrate 4 and the second supporting substrate 6 and the semiconductor element layer 3 can be performed using an optical method. This allows for more precise cleaving of the semiconductor element layer 3.

In the method for manufacturing the semiconductor element of the present embodiment, a supporting member attaching step and a detachment step may be performed after the cleaving step.

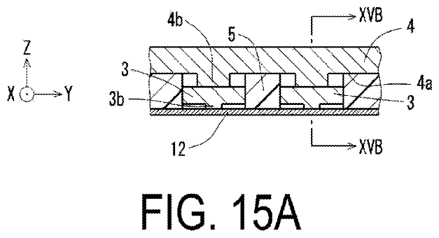

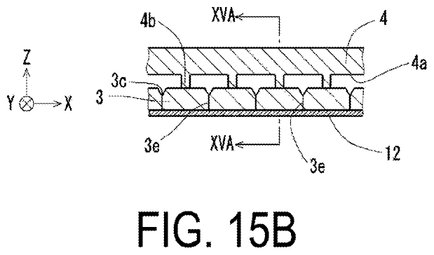

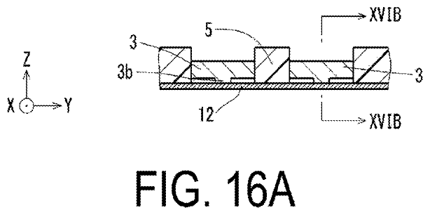

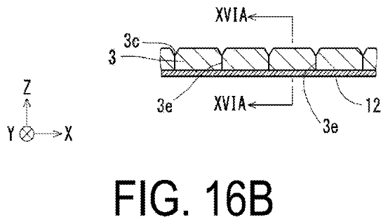

Each of the steps described above will be described primarily with reference to FIGS. 15A, 15B, 16A, and 16B.

In the supporting member attaching step, the second supporting substrate 6 is first removed. Next, as illustrated in FIGS. 15A and 15B, for example, the supporting member 12 is attached to the surface of the bonding material 5 on the side opposite to the first supporting substrate 4 side. For example, a dicing tape, a dicing sheet, or the like can be used as the supporting member 12.

In the detachment step, as illustrated in FIGS. 16A and 16B, for example, the supporting member 12, the bonding material 5, and the semiconductor element layer 3 are detached from the first supporting substrate 4. As a result, the semiconductor element layer 3 held by the supporting member 12 by way of the bonding material 5 is obtained. The semiconductor element layer 3 is held by the bonding material 5, for example, as illustrated in FIG. 16A. According to the method for manufacturing a semiconductor element of the present embodiment, the handling properties of the semiconductor element layer 3 can be enhanced. The semiconductor element layer 3 held by the supporting member 12 can be singulated into a plurality of element parts by, for example, stretching the supporting member 12 in the planar direction (XY-plane direction).

### Third Embodiment

Next, a method for manufacturing a semiconductor element according to a third embodiment will be described. The method for manufacturing a semiconductor element according to the third embodiment includes an element layer forming step, and as a step of disposing a reinforcement material, a resist layer forming step, a resist portion forming step, and a peeling step. The element layer forming step of the method for manufacturing a semiconductor element according to the third embodiment is the same as the element layer forming step of the method for manufacturing the semiconductor element according to the first embodiment. In the following, a detailed description of the element layer forming step is omitted for the method for manufacturing the semiconductor element according to the third embodiment.

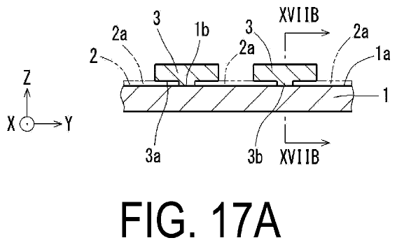

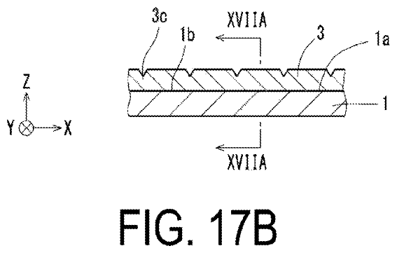

Each of the steps described above will be described primarily with reference to FIGS. 17A, 17B, 18A, 18B, 19A, 19B, 20A, and 20B.

In the element layer forming step, for example, as illustrated in FIGS. 17A and 17B, similar to the element layer forming step of the first embodiment, the semiconductor element layer 3 is formed on the first surface 1a of the ground substrate 1, and a plurality of frangible portions 3c are formed in the semiconductor element layer 3.

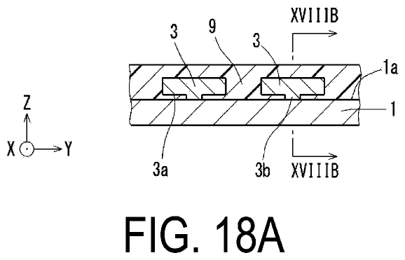

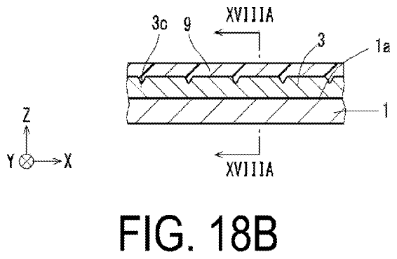

In the resist layer forming step, as illustrated in FIGS.18A and 18B, for example, the resist layer 9 is formed that covers the semiconductor element layer 3 and that has one part entering a gap between the first surface 1a of the ground substrate 1 and the second surface 3a of the semiconductor element layer 3. The resist layer 9 can be formed, for example, by applying a resist material to the first surface 1a of the ground substrate 1. The resist material has light curing properties or light softening properties. For example, a liquid resist material for photolithography, a dry film, or the like can be used as the resist material.

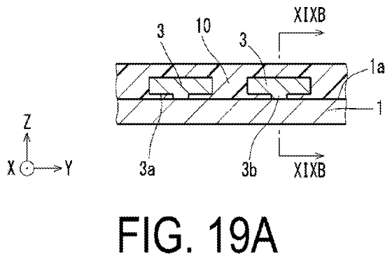

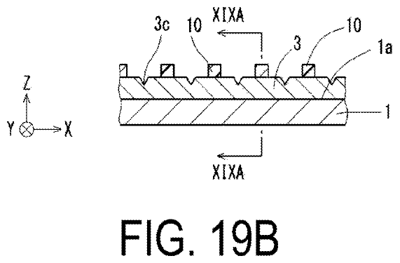

In the resist portion forming step, the resist layer 9 is selectively removed using a photolithography method, dry etching, or wet etching. As a result, as illustrated in FIGS. 19A and 19B, for example, a plurality of resist portions 10 are formed on the first surface 1a. For example, a Cr matrix, a Ti mask, a W mask, or the like can be used as the photomask used in the photolithography method.

Each of the resist portions 10 partially covers the semiconductor element layer 3, and has one part entering the gap between the first surface 1a and the second surface 3a. Each resist portion 10 is in contact with the second surface 3a of the semiconductor element layer 3, a surface on the side opposite to the second surface 3a, and both side surfaces in a second direction (Y direction) of the semiconductor element layer 3. The plurality of resist portions 10 may be located at predetermined intervals along the first direction (X direction). The interval between adjacent resist portions 10 may be substantially the same as the interval between adjacent frangible portions 3c in the first direction, that is, the dimension in the first direction of the semiconductor element to be manufactured. Each of the resist portions 10 may be located midway between the two frangible portions 3c adjacent to the resist portion 10 in the first direction.

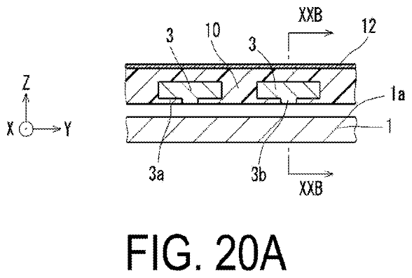

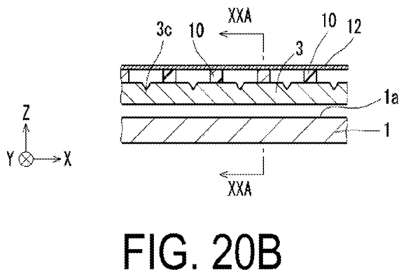

In the peeling step, as illustrated in FIGS. 20A and 20B, for example, the supporting member 12 is attached to the surface on the side opposite to the ground substrate 1 of the plurality of resist portions 10. Next, the supporting member 12, the plurality of resist portions 10, and the semiconductor element layer 3 are peeled off from the ground substrate 1. For example, a dicing tape, a dicing sheet, or the like can be used as the supporting member 12.

In the present embodiment, the semiconductor element layer 3 formed on the first surface 1a of the ground substrate 1 is peeled off from the ground substrate 1 while being held by the resist portion 10. As a result, the resist portion 10 functions as a reinforcement material that reinforces the semiconductor element layer 3, and the pattern of the semiconductor element layer 3 grown on the ground substrate 1 can be made less likely to break when it is peeled off from the ground substrate 1, thereby improving the handling properties of the semiconductor element layer 3.

In the method for manufacturing a semiconductor element of the present embodiment, a supporting substrate preparing step and a cleaving step may be performed after the peeling step.

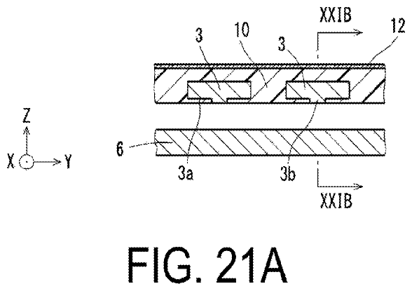

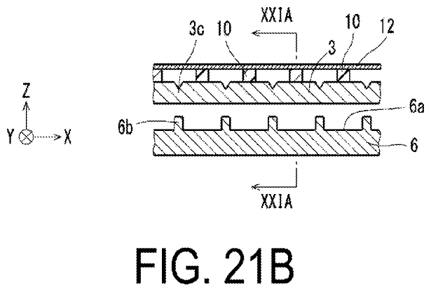

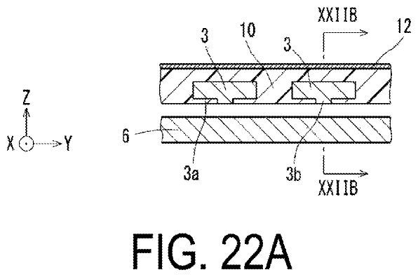

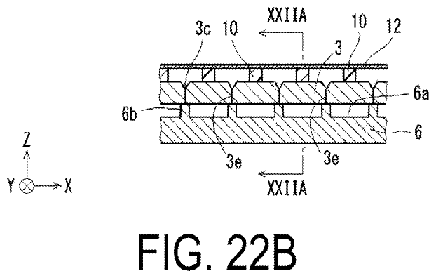

Each of the steps described above will be described primarily with reference to FIGS. 21A, 21B, 22A, and 22B.

In the supporting substrate preparing step, first, a supporting substrate 6 having a fifth surface 6a is prepared. As a supporting substrate 6, for example, a SiO₂ substrate, an ITO substrate, a Si substrate, or the like can be used. A plurality of third protruding portions 6b are located on the fifth surface 6a of the supporting substrate 6. The fifth surface 6a on which the plurality of third protruding portions 6b are located can be formed by, for example, dry etching or wet etching. For example, as illustrated in FIGS. 21A and 21B, the plurality of third protruding portions 6b may be located at predetermined intervals in the linear direction along the fifth surface 6a. The interval between adjacent third protruding portions 6b may be substantially the same as the interval between adjacent frangible portions 3c in the first direction, that is, the dimension in the first direction of the semiconductor element to be manufactured.

Next, in the supporting substrate preparing step, the supporting substrate 6 is located such that the fifth surface 6a faces the second surface 3a of the semiconductor element layer 3, and the plurality of third protruding portions 6b are alternately adjacent to the plurality of resist portions 10 in plan view. In the second supporting substrate preparing step, the supporting substrate 6 may be located so that the plurality of third protruding portions 6b overlap corresponding ones of the plurality of frangible portions 3c in plan view.

In the cleaving step, the supporting substrate 6 is pressed against the supporting member 12. As a result, stress is generated in portions of the semiconductor element layer 3 against which the plurality of protruding portions 6b respectively abut, and a plurality of cleaving surfaces 3e are formed in the semiconductor element layer 3, for example, as illustrated in FIG. 22B. In the present embodiment, the second supporting substrate 6 is pressed against the first supporting substrate 4 in a state where the plurality of third protruding portions 6b are alternately adjacent to the plurality of resist portions 10 in plan view. This allows for precise cleaving of the semiconductor element layer 3 because stress can be concentrated at the frangible portions 3c. When the plurality of third protruding portions 6b overlap corresponding ones of the plurality of frangible portions 3c in plan view, stress can be effectively concentrated at the frangible portions 3c, thereby allowing for more precise cleaving of the semiconductor element layer 3. When a transparent substrate such as a SiO₂ substrate or an ITO substrate is used as the supporting substrate 6, positioning of the supporting substrate 6 and the semiconductor element layer 3 can be performed using an optical method. This allows for more precise cleaving of the semiconductor element layer 3. In the cleaving step, ultrasonic vibrations, for example, may be used to further facilitate cleaving.

After the cleaving step, the supporting substrate 6 is removed to obtain the semiconductor element layer 3 held by the supporting member 12 by way of the bonding material 5. The semiconductor element layer 3 held by the supporting member 12 can be singulated into a plurality of element parts by, for example, stretching the supporting member 12 in the planar direction (XY-plane direction).

### Semiconductor Element Body

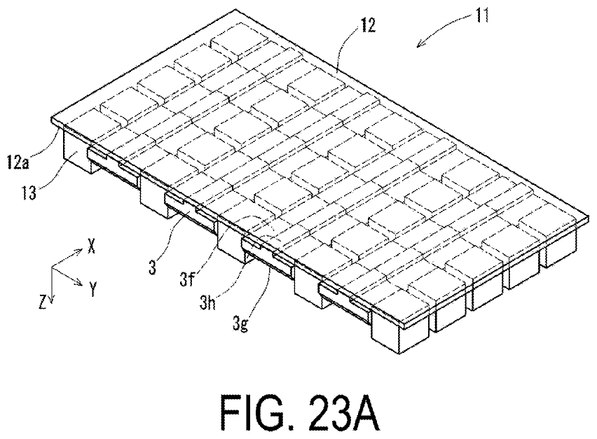

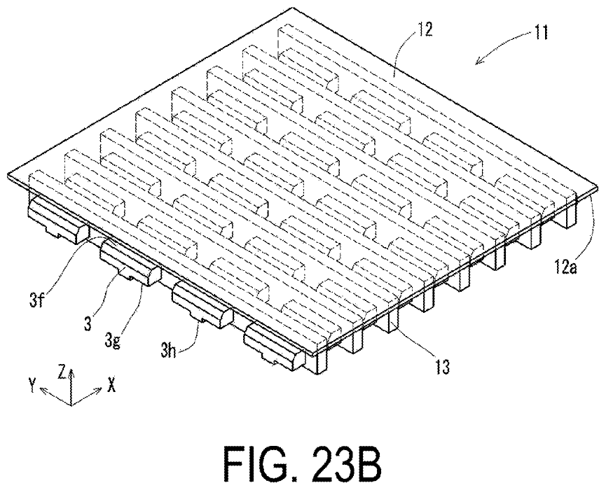

An embodiment of the semiconductor element body of the present disclosure will be described primarily with reference to FIGS. 23A and 23B.

As illustrated in FIGS. 23A and 23B, for example, the semiconductor element body 11 includes a supporting member 12, a holding member 13, and a semiconductor element layer 3. The supporting member 12 has a main surface 12a. The supporting member 12 may be, for example, a dicing tape, a dicing sheet, or the like. The supporting member 12 may be, for example, a SiO₂ substrate, an ITO substrate, or a Si substrate. The holding member 13 is located on the main surface 12a of the supporting member 12. The holding member 13 is formed from, for example, a resin material or the like.

The semiconductor element layer 3 is held on the main surface 12a of the supporting member 12 by way of the holding member 13. The semiconductor element layer 3 extends in a first direction (X direction) parallel to the main surface 12a of the supporting member 12. The semiconductor element layer 3 has an opposing surface 3f facing the supporting member 12 and a back surface 3e on a side opposite to the opposing surface 3f. The semiconductor element layer 3 includes projections 3h extending in a first direction on one of the opposing surface 3f and the back surface 3g. The projections 3h are located on a part of the opposing surface 3f or the back surface 3g in a second direction (Y direction) intersecting the first direction in plan view. Each of the projections 3h may be located at a center portion of the opposing surface 3f or the back surface 3g in the second direction. The semiconductor element layer 3 may be a semiconductor element layer 3 formed in the element layer forming step of the first embodiment, the second embodiment, or the third embodiment.

According to the semiconductor element body 11 of the present embodiment, a semiconductor element body with improved handling properties can be provided. For example, a pick up operation or the like that involves gripping the holding member 13 is facilitated, and positioning and fitting operations using the shape of the projections 3h of the semiconductor element layer 3 are facilitated.

In the semiconductor element body 11 illustrated in FIG. 23A, the heights of the semiconductor element layer 3 and the holding member 13 are different. Thus, the fitting operation using this step difference, the fine position adjusting operation in the height direction, and the like can be easily performed. Furthermore, the semiconductor element layer 3 can be prevented from directly touching the installation surface.

Furthermore, in the semiconductor element body 11 illustrated in FIG. 23B, when handling the semiconductor element body 11 with the holding member 13 sandwiched therebetween, a pick up operation can be performed by gripping the side surface of the holding member 13. Furthermore, the positioning operation can be easily performed as the holding member 13 is located at the center of the semiconductor element layers 3.

Therefore, by avoiding direct contact with the semiconductor element layer 3, the handling properties can be improved, and it is possible to avoid damage or breakage of the semiconductor element layer 3d.

The present disclosure has been described in detail above, but the present disclosure is not limited to the embodiments described above, and various modifications, improvements, and the like can be made within a scope not departing from the gist of the present disclosure. Needless to say, all or a part of each of the above-described embodiments can be appropriately combined in a non-contradicting range.

### REFERENCE SIGNS LIST

1 Ground substrate
1a One main surface (first surface)
1b Growth region
1c Other main surface
2 Mask
2a Band-like portion
3 Semiconductor element layer
3a Second surface
3b Connecting portion
3c Frangible portion
3e Cleaving surface
3f Opposing surface
3g Back surface
3h Projection
4 First supporting substrate
4a Third surface
4b First protruding portion
5 Bonding material
6 Second supporting substrate (supporting substrate)
6a Fourth surface, fifth surface
6b Second protruding portion, third protruding portion
7 Resist material
8 Protective film
8a Main surface
9 Resist layer
10 Resist portion
11 Semiconductor element body
12 Supporting member
12a Main surface
13 Holding member
31 Semiconductor element precursor (element part)
31a Both end faces
31b Side surface
32 Semiconductor element

1. A method for manufacturing a semiconductor element comprising:
an element layer forming step of forming, on a first surface of a ground substrate, a semiconductor element layer comprising a second surface facing the first surface, and a connecting portion projecting out from the second surface toward a side of the first surface and connecting to the first surface;
a disposing step of disposing a reinforcement material that reinforces the semiconductor element layer around at least a part of the semiconductor element layer; and
a peeling step of peeling off the reinforcement material and the semiconductor element layer.

2. The method for manufacturing a semiconductor element according to claim 1, wherein
the disposing step of disposing the reinforcement material comprises:
a first supporting substrate preparing step of positioning a first supporting substrate, that comprises a third surface and a plastic bonding material located on the third surface as the reinforcement material, with the third surface facing the first surface, and
a pressing step of softening the plastic bonding material, pressing the first supporting substrate against the ground substrate, and causing the plastic bonding material to enter a gap between the first surface and the second surface; and
further comprising a peeling step of curing the plastic bonding material and peeling off the first supporting substrate, the plastic bonding material, and the semiconductor element layer from the ground substrate.

3. The method for manufacturing a semiconductor element according to claim 2, wherein
the element layer forming step comprises forming, on the first surface, the semiconductor element layer comprising the connecting portion that extends in a first direction along the first surface and that is located on a part of the second surface in a second direction intersecting the first direction in a plan view.

4. The method for manufacturing a semiconductor element according to claim 3, wherein
the first supporting substrate preparing step comprises positioning the first supporting substrate with the third surface facing the first surface, the first supporting substrate comprising a plurality of first protruding portions located at predetermined intervals along the first direction on the third surface and the plastic bonding material covering the plurality of first protruding portions located on the third surface.

5. The method for manufacturing a semiconductor element according to claim 2,
comprising after the peeling step;
a second supporting substrate preparing step of positioning a second supporting substrate, that comprises a fourth surface and a plurality of second protruding portions located on the fourth surface, with the fourth surface facing the third surface, and the plurality of first protruding portions and the plurality of second protruding portions alternating in a plan view, and
a cleaving step of softening the cured plastic bonding material and pressing the second supporting substrate against the first supporting substrate to form a plurality of cleaving surfaces on the semiconductor element layer.

6. The method for manufacturing a semiconductor element according to claim 2,
comprising after the peeling step;
a removing step of removing a portion of the cured plastic bonding material overlapping the semiconductor element layer in a plan view;
a second supporting substrate preparing step of positioning a second supporting substrate, that comprises a fourth surface and a plurality of second protruding portions located on the fourth surface, with the fourth surface facing the second surface, and the plurality of first protruding portions and the plurality of second protruding portions alternating in a plan view, and
a cleaving step of pressing the second supporting substrate against the first supporting substrate to form a plurality of cleaving surfaces on the semiconductor element layer.

7. The method for manufacturing a semiconductor element according to claim 2, comprising:
a frangible portion forming step of forming a plurality of frangible portions on the semiconductor element layer is performed between the element layer forming step and the first supporting substrate preparing step.

8. The method for manufacturing a semiconductor element according to claim 7, wherein
the first supporting substrate comprising a plurality of first protruding portions and the second supporting substrate comprising a plurality of second protruding portions and
in the frangible portion forming step, the plurality of first protruding portions and the plurality of frangible portions are alternately positioned with the plurality of second protruding portions and the plurality of frangible portions overlapping in a plan view.

9. The method for manufacturing a semiconductor element according to claim 1, wherein
the disposing step of disposing the reinforcement material comprises:
a resist layer forming step of forming a resist layer that covers the semiconductor element layer as the reinforcement material, and that includes one part entering a gap between the first surface and the second surface, and
a resist portion forming step of forming a plurality of resist portions that partially cover the semiconductor element layer, and that have one part entering a gap between the first surface and the second surface by selectively removing the resist layer; and
further comprising a peeling step of attaching a supporting member to a surface of the plurality of resist portions on a side opposite to the ground substrate, and peeling off the supporting member, the plurality of resist portions, and the semiconductor element layer from the ground substrate.

10. The method for manufacturing a semiconductor element according to claim 9, wherein
the element layer forming step comprises forming, on the first surface, the semiconductor element layer comprising the connecting portion that extends in a first direction along the first surface and that is located on a part of the second surface in a second direction intersecting the first direction in a plan view.

11. The method for manufacturing a semiconductor element according to claim 9,
comprising after the peeling step;
a supporting substrate preparing step of positioning a supporting substrate, that comprises a fifth surface and a plurality of third protruding portions formed on the fifth surface, with the fifth surface facing the second surface and the plurality of resist portions and the plurality of third protruding portions alternating in a plan view, and
a cleaving step of pressing the supporting substrate against the supporting member to form a plurality of cleaving surfaces on the semiconductor element layer.

12. The method for manufacturing a semiconductor element according to claim 9, wherein
a frangible portion forming step of forming a plurality of frangible portions on the semiconductor element layer is performed between the semiconductor layer forming step and the resist layer forming step.

13. The method for manufacturing a semiconductor element according to claim 11, wherein
in the frangible portion forming step, the plurality of third protruding portions and the plurality of frangible portions are made to overlap in a plan view.

14. A semiconductor element body comprising:
a supporting member comprising a main surface;
a holding member located above the main surface; and
a semiconductor element layer that is held on the main surface by the holding member, extends in a first direction along the main surface, and comprises an opposing surface facing the main surface and a back surface on a side opposite to the opposing surface, wherein
a projection extending in the first direction is located on one of the opposing surface and the back surface of the semiconductor element layer.
